(19) United States
(12) Patent Application Publication
(10) Pub. No.: US 2005/0151273 A1
(43) Pub. Date: Jul. 14, 2005

(54) Semiconductor chip package

(76) Inventors: Richard Willson Arnold, McKinney, TX (US); Marvin Wayne Cowens, Plano, TX (US); Charles Anthony Odegard, McKinney, TX (US)

Correspondence Address: TEXAS INSTRUMENTS INCORPORATED, P O BOX 655474, M/S 3999, DALLAS, TX, 75265, US

(21) Appl. No.: 10/749,111

(22) Filed: Dec. 30, 2003

(51) Int. Cl. H01L 23/48

(52) U.S. Cl. 257/788

(57) ABSTRACT

A semiconductor chip package includes an integrated circuit chip and a substrate. A chip contact pad is formed on a first side of the chip. A stud is formed on the chip contact pad from wire using a wire bonding machine. The stud has a partially squashed ball portion bonded to the chip contact pad. The stud also has an elongated portion extending from the partially squashed ball portion. A first layer of insulating material is on a first side of the substrate. A bottomed well is formed in the first layer and opens to the first side of the substrate. A first conductive material at least partially fills the well. The first conductive material is electrically connected to at least one trace line in the substrate. The stud is partially embedded in the first conductive material to form an electrical connection between the chip and the substrate.

### TECHNICAL FIELD

The present invention generally relates to packaging of semiconductor chips. In one aspect it relates more particularly to an integrated circuit chip electrically connected to a substrate in a flip-chip configuration.

### BACKGROUND

Integrated circuit devices typically include a semiconductor die or chip that is assembled in a package. A package typically has a substrate portion to which the chip is electrically connected. Usually the substrate is larger than the chip and has larger terminals, leads, or electrical contact points than that of the chip to allow for ease of electrically connecting a packaged chip onto a circuit board (e.g., while assembling a circuit board for a system). One such package configuration is a flip-chip package.

An example of a conventional flip-chip package 20 is shown in FIG. 1. In this example, the chip 22 is electrically connected to the substrate 24 by an array of solder bumps 26. The substrate 24 in this example has an array of solder balls 28 (i.e., ball grid array or BGA), which may be used to attach the packaged chip 20 to a circuit board (not shown), for example. Typically, an underfill material 30 is fed into the free space or gap between the chip 22 and the substrate 24 after the chip 22 is electrically connected to the substrate 24 via the solder bumps 26. In FIG. 1, portions of the underfill material 30 have been cut away to illustrate some of the solder bumps 26 therein. At some point after the chip 22 is electrically connected to the substrate 24 and the underfill material 30 is placed and cured, a lid 32 is typically placed over the chip 22. The lid 32 is shown in phantom lines in FIG. 1 for purposes of illustration. In addition to protecting the chip 22 in the package 20, this lid 32 may be made from aluminum and act as a heat sink to provide better cooling for the chip 22, for example.

One of the purposes of the underfill material 30 is to more evenly distribute the stresses between the chip 22 and the substrate 24 to reduce the stresses experienced by the solder bumps 26, solder bump joints, and/or circuitry layers above/below solder joints. Such stresses are caused, at least in part, by different coefficients of thermal expansion between the chip 22, the solder bumps 26, and the substrate 24 (i.e., coefficient of thermal expansion mismatch). The chip 22 is typically made from a silicon wafer, the substrate 24 is typically made from organic material having copper lines and vias extending therein, and the solder bumps 26 are typically made from a metal compound having a low melting point, for example. Thus, temperature changes (e.g., during use of the chip 22) cause stress on the solder bumps 26 connecting the chip 22 to the substrate 24 due to the different rates of material expansion/contraction between the chip 22 and the substrate 24. The underfill material 30 may also act as an adhesive to help retain the chip 22 to the substrate 24 so that not just the solder bumps 26 are holding the chip 22 in place. This further reduces stress exerted on the solder bumps 26.

Fabricating and assembling a flip-chip package using solder bumps, e.g., as described above, can be more expensive than other methods of attaching a chip to a substrate (e.g., wire bonding). Also, connections using wire bonding are often stronger than connections using solder bumps. Furthermore, many manufacturing facilities already have wire bonding machines. However, wire bonding is typically not suited for flip-chip configurations, and flip-chip configurations are preferred by some manufacturers. Hence, it would be desirable to provide a way to attach a chip to a substrate using a wire bonding machine and using a flip-chip configuration.

### SUMMARY OF THE INVENTION

The problems and needs outlined above may be addressed by embodiments of the present invention. In accordance with one aspect of the present invention, a semiconductor chip package is provided, which includes an integrated circuit chip, a chip contact pad, a stud, and a substrate. The chip contact pad is formed on a first side of the chip. The stud is formed on the chip contact pad. The stud is formed from wire using a wire bonding machine. The stud has a partially squashed ball portion bonded to the chip contact pad. The stud also has an elongated portion extending from the partially squashed ball portion. The substrate includes a first layer of insulating material, a well, a first conductive material, and a second layer. The first layer of insulating material is on a first side of the substrate. The well is formed in the first layer and opens to the first side of the substrate. The well has a bottom. The first conductive material at least partially fills the well. The second layer has conductive trace lines formed therein. The first conductive material is electrically connected to at least one of the trace lines. The stud is partially embedded in the first conductive material to form an electrical connection between the chip and the substrate. The first side of the chip faces the first side of the substrate.

In accordance with another aspect of the present invention, a method of forming a semiconductor chip package is provided. This method includes the following steps described in this paragraph, and the order of steps may vary. An integrated circuit chip is provided. The chip includes a chip contact pad formed on a first side of the chip. A wire in a wire bonding machine is provided. A tip of the wire has a ball-shaped portion. The ball-shaped portion of the wire is wire bonded onto the chip contact pad with the wire bonding machine. The ball-shaped portion becomes partially squashed during the wire bonding. The wire is severed so that an elongated portion of the wire remains extending from the partially squashed ball-shaped portion to form a stud. A substrate is provided, which includes a first layer of insulating material, a well, a first conductive material, and a second layer. The first layer of insulating material is on a first side of the substrate. The well is formed in the first layer and opens to the first side of the substrate. The well has a bottom. The first conductive material at least partially fills the well. A second layer has conductive trace lines formed therein. The first conductive material is electrically connected to at least one of the trace lines. At least part of the elongated portion of the stud is immersed into the first conductive material to form an electrical connection between the chip and the substrate. The first side of the chip faces the first side of the substrate.

In accordance with still another aspect of the present invention, a semiconductor chip package is provided, which includes an integrated circuit chip, a chip contact pad, a stud, a substrate, and a support member. The chip contact pad is formed on a first side of the chip. The stud is formed on the chip contact pad. The stud is formed from wire using a wire bonding machine. The stud has a partially squashed ball portion bonded to the chip contact pad. The stud has an elongated portion extending from the partially squashed ball portion. The substrate includes a first layer of insulating material, a well, a conductive liner, a first conductive material, and a second layer. The first layer of insulating material is on a first side of the substrate. The well is formed in the first layer and opens to the first side of the substrate. The well has a bottom. The conductive liner at least partially lines the well. The first conductive material at least partially fills the well. The second layer has conductive trace lines formed therein. The first conductive material is electrically connected to at least one of the trace lines via the conductive liner. The support member extends from the first layer of the substrate between the chip and the substrate. The stud is partially embedded in the first conductive material to form an electrical connection between the chip and the substrate. The first side of the chip faces the first side of the substrate. The chip is at least partially supported by the support member.

The foregoing has outlined rather broadly features of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The following is a brief description of the drawings, which illustrate exemplary embodiments of the present invention and in which:

FIG. 1 is a side view of a flip-chip package of the prior art;

FIG. 2 is a side view of a flip-chip package in accordance with a first embodiment of the present invention;

FIG. 3 is an enlarged cross-section view for a portion of FIG. 2;

FIG. 4 is a side view of a flip-chip package in accordance with a second embodiment of the present invention; and

FIG. 5 is an enlarged cross-section view for a portion of FIG. 4.

### DETAILED DESCRIPTION OF ILLUSTRATIVE EMBODIMENTS

Referring now to the drawings, wherein like reference numbers are used herein to designate like elements throughout the various views, illustrative embodiments of the present invention are shown and described. The figures are not necessarily drawn to scale, and in some instances the drawings have been exaggerated and/or simplified in places for illustrative purposes only. One of ordinary skill in the art will appreciate the many possible applications and variations of the present invention based on the following illustrative embodiments of the present invention.

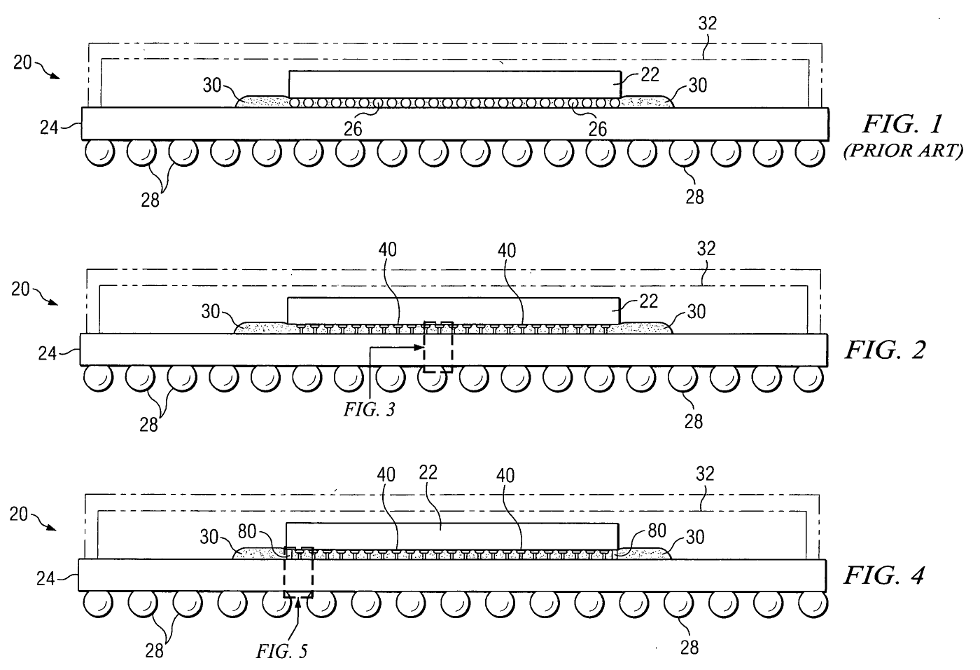

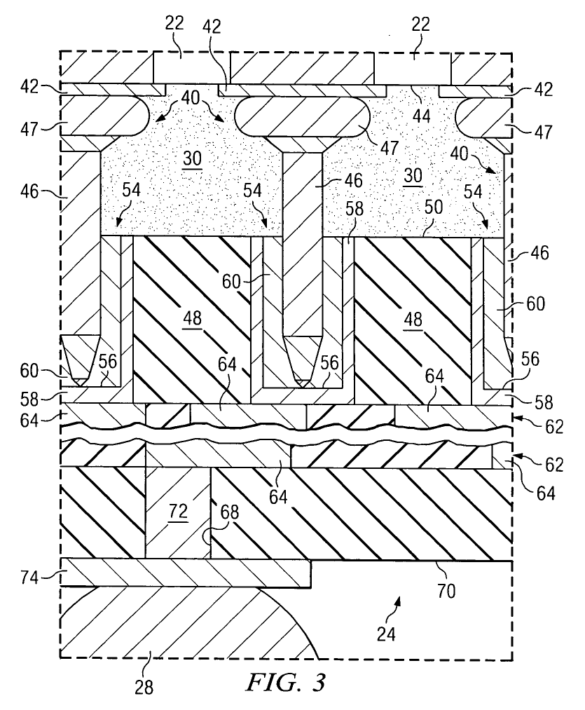

FIGS. 2 and 3 illustrate a semiconductor chip package 20 in accordance with a first embodiment of the present invention. FIG. 2 is a side view of the package 20. As in FIG. 1, portions of the underfill material 30 have been cut-away for purposes of illustrating the studs 40 in FIG. 2. Also, the lid 32 is shown in phantom lines in FIG. 2 for purposes of illustration. In FIG. 2, an integrated circuit chip 22 is electrically connected to a substrate 24 in a flip-chip configuration.

FIG. 3 is an enlarged portion of FIG. 2 showing a cross-section of the package 20. First the chip part of the package 20 will be described. Chip contact pads 42 are formed on a first side 44 of the chip 22. The first side 44 of the chip 22 faces the substrate 24. At least some of the chip contact pads 42 have studs 40 bonded thereto. The studs 40 are formed from wire using a wire bonding machine (not shown). Before being bonded, the studs 40 begin as a wire having a ball-shaped tip (not shown) that is fed from a wire bonding machine (not shown), as in a typical wire bonding procedure for example. The ball-shaped tip of the wire is bonded to its respective chip contact pad 42 by the wire bonding machine. The ball-shaped tip becomes at least partially squashed by the wire bonding machine (e.g., by the capillary). After bonding the tip of the wire to the chip contact pad 42, a predetermined length of the wire is drawn out to provide the elongated portion 46 of the stud 40. Then, the wire bonding machine severs the wire to form a stud 40, as shown in FIG. 3 for example. Hence, the stud 40 has a partially squashed ball portion 47 and an elongated portion 46. The elongated portion 46 extends from the partially squashed ball portion 47. This process is repeated until all of the studs 40 are formed on the first side 44 of the chip 22. Some or all of the studs 40 may be formed at the same time (i.e., in parallel), which will likely depend on the wire bonding machine.

The chip contact pads 42 may be made from any of a variety of appropriate materials, including for example (but not limited to): gold, aluminum, nickel, palladium, tungsten, copper, or combinations thereof. The studs 40 may be made from any of a variety of appropriate materials, including for example (but not limited to): gold, silver, copper, aluminum, lead, tin, solder, and combinations thereof. The wire bonding machine may or may not use ultrasonic energy during bonding, depending at least in part on the materials used for the chip contact pads 42 and the studs 40. It is preferred to use gold for the studs 40 and gold as the outermost, exposed material of the chip contact pads 42 (hence, a gold-on-gold bond). One of the advantages of using gold for the studs 40 and for the chip contact pads 42 is that it may allow for bonding at a low capillary force; thus lowering stress exerted on the chip 22 during bonding. Reducing stress on the chip is becoming a growing concern where weak, low-k dielectric materials are implemented into the chip structure, for example. Also, a gold-on-gold bond may reduce or eliminate the need for using ultrasonic energy and/or high heat to form a bond between the stud 40 and the chip contact pad 42, which may be advantageous as well. In such case where the forces exerted on the chip 22 are lowered by using a gold-on-gold bond, for example, the chip contact pads 42 may be moved to the center portion of the chip 22 as well; thus allowing for the placement of chip contact pads 42 at any or almost any location on the first chip side 44. This may allow for more chip contact pads 42 per chip area and/or more spacing between chip contact pads 42.

Still referring to FIG. 3, the substrate portion of the package 20 is described next. A first layer 48 of insulating material is provided on a first side 50 of the substrate 24, as shown in FIG. 3. This first layer 48 may be a single layer, a composite layer, and/or multiple layers. In FIG. 3, the first layer 48 is shown as a single layer for purposes of illustration. The first side 50 of the substrate 24 faces the chip 22. Wells 54 are formed in the first substrate layer 48 and open to the first substrate side 50. The wells 54 have bottoms 56. In a preferred embodiment, a conductive liner 58 at least partially lines at least some of the wells 54. In FIG. 3, a conductive liner 58 is shown lining the walls and bottom 56 for each well 54, for example. A first conductive material 60 at least partially fills each well 54.

The first substrate layer 48 may be made from any of a variety of appropriate materials, including (but not limited to): organic material (e.g., as commonly used in low cost substrates), ceramic, fiberglass, resin, plastic, polymer, and combinations thereof, for example. The conductive liner 58 may be made from any of a variety of appropriate materials, including (but not limited to): metal, copper, silver, gold, aluminum, titanium, tantalum, or combinations thereof, for example. In a preferred embodiment, the wells 54 have copper liners 58 formed in organic material.

The first conductive material 60 may be any of a variety of appropriate materials, including (but not limited to): solder, conductive adhesive, conductive polymer material, metal compounds, or combinations thereof, for example. If solder is used for the first conductive material 60, it is preferably an ultra fine pitch solder that allows for pitches of less than 90 μm, for example. Such ultra fine pitch solder may be screen printed into the wells 54, for example. Another preferred solder is Super Solder™ by Harima Chemicals, for example, which may have a combination of Sn, RCOO—Cu, RCOO—Ag, and flux. However, many other suitable solders are available and may be used as well in an embodiment of the present invention. In FIG. 3, a lead-free solder is used as the first conductive material 60, for example. When solder is used as the first conductive material 60 in the wells 54, it may be deposited into the wells 54 and then reflowed (i.e., heated to make the solder penetrable by the stud 40) when inserting the studs 40 into the solder by heating the substrate 24, for example.

When a conductive adhesive (e.g., conductive polymer material) is used as the first conductive material 60 in the wells 54, it may be deposited into the wells 54 and the studs 40 may be inserted into the first conductive material 60 before it cures, for example. In a preferred embodiment, the conductive adhesive may remain uncured until it is treated to provide adequate time for inserting the studs 40. Such treatment may be provided by heating the adhesive, adding another chemical to the adhesive, exposing the adhesive to a certain gas or environment, or combinations thereof, for example. However, in other embodiments, the conductive adhesive may simply cure over a specified period of time. In a preferred embodiment, the conductive adhesive retains a specified amount of flexibility after curing to allow for slight movement of the stud 40 therein for relieving thermal stress, for example. In this or other embodiments, including those with solder as the first conductive material 60, flexibility may also be provided by the wire stud 46 spanning between chip 22 and substrate 24. The flexibility provides relief from stress caused by, e.g., different CTE of the different materials.

When the chip 22 is electrically connected to the substrate 24, as shown in FIG. 3 for example, the studs 40 are at least partially embedded in the first conductive material 60 in the well 54 to form electrical connections between the chip 22 and the substrate 24. Preferably, the studs 40 are formed on the chip 22 before the studs 40 are inserted into the wells 54. Also, the wells 54 are preferably filled (or partially filled) with the first conductive material 60 prior to inserting the studs 40 into the wells 54.

After the studs 40 are inserted into the first conductive material 60 in the wells 54 to interconnect the chip 22 with substrate 24, an underfill material 30 may be provided between the chip 22 and the substrate 24, as shown in FIGS. 2 and 3 for example. The underfill material 30 may be conventional underfill material, for example.

Focusing again on the substrate 24 of FIG. 3, a second substrate layer 62 having conductive trace lines 64 formed therein is located under the first substrate layer 48. The first conductive material 60 for at least one well 54 is electrically connected to at least one conductive trace line 64 in the second substrate layer 62. Hence, when a well liner 58 covers the bottom 56 of a well 54, as shown in FIG. 3, the first conductive material 60 is electrically connected to one or more traces 64 via the well liner 58. A substrate 24 of an embodiment may have one or more layers of conductive trace lines (e.g., as the second substrate layer 62). Two of such layers 62 are shown in FIG. 3 and there may be any number of additional layers 62 there between, for example. The conductive trace lines 64 may be made from any of a variety of appropriate materials, including (but not limited to): metal, copper, aluminum, gold, or combinations thereof, for example. An insulating material (e.g., organic material) may be used in the layers 62 containing the conductive trace lines 64, as is conventionally provided in a substrate 24 for example.

Vias 68 extend to a second side 70 of the substrate 24 and are filled with a second conductive material 72 (e.g., metal), as shown in FIG. 3. Terminals 74 are located on the second substrate side 70. The conductive vias 68 provide electrical connections between terminals 74 and conductive trace lines 64. The terminals 74 may have solder balls 28 formed thereon to provide a ball grid array structure, as shown in FIGS. 2 and 3 for example. Thus, in the example of FIG. 3, the solder ball 28 shown on the second substrate side 70 is electrically connected to one of the contact pads 42 on the chip 22 through a stud 40, a well 54 filled with the first conductive material 60, at least one conductive trace line 64, a conductive via material 72, and a terminal 74, for example.

Note in FIG. 3 that some or all of the studs 40 may rest on the bottom 56 of wells 54, depending on the depth of insertion for the studs 40 and depending upon the consistency of stud lengths. The chip 22 may be temporarily held above the substrate 24 so that few or none of the studs 40 reach the well bottoms 56 after the studs 40 are inserted into the wells 54 and while the first conductive material 60 is cured or cooled to a solid form.

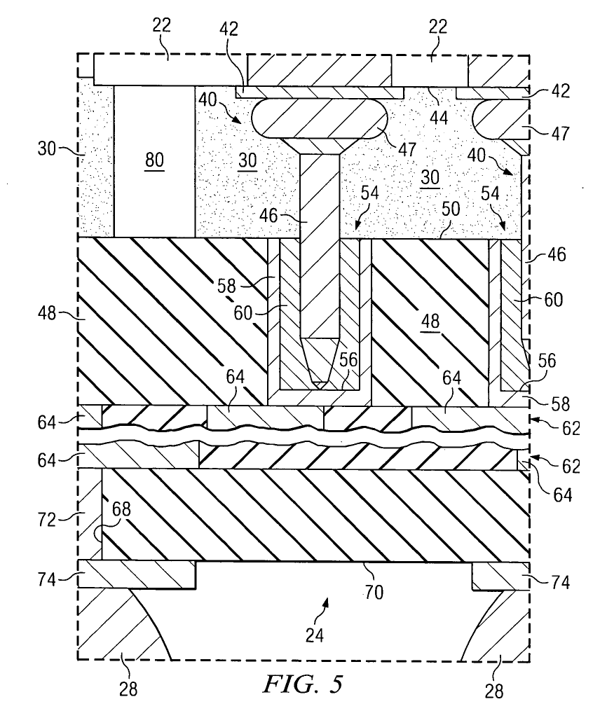

FIGS. 4 and 5 illustrate a semiconductor chip package 20 in accordance with a second embodiment of the present invention. The second embodiment is similar to the first embodiment (see FIGS. 2 and 3), except that the choice of first conductive material 60 is changed and support members 80 are provided (see FIGS. 4 and 5). FIG. 4 is a side view of the package 20 of the second embodiment. As in FIGS. 1 and 2, portions of the underfill material 30 have been cut-away for purposes of illustrating the studs 40 and support members 80 in FIG. 4. FIG. 5 is an enlarged portion of FIG. 4 showing a cross-section of the package 20 in more detail.

Referring to FIG. 5, a support member 80 is shown extending from the first substrate layer 48 in this example. The support member 80 may be an integral part of the first substrate layer 48. In another embodiment, the support member 80 may be formed on and/or attached to the first substrate layer 48. In still another embodiment, the support member 80 may be part of, may extend from, and/or may be attached to the chip 22. The material used for the support members 80 may selected from any of a variety of appropriate materials, including (but not limited to): polymer, organic material, metal, plastic, ceramic, fiberglass, resin, silicon, and combinations thereof, for example. Preferably, the support members 80 all have a same height. But in other embodiments, the support members 80 may not all have the same height (e.g., tilted chip 22 relative to the substrate 24), for example.

In a preferred configuration, the chip 22 rests on and is at least partially supported by the support members 80. The use of support members 80 may be advantageous in situations where the studs 40 do not have consistent lengths. Also, by having the chip 22 rest on the support members 80, the distance between the chip 22 and the substrate 24 may be controlled by the height of the support members 80 rather than the length of the studs 40 and/or the depth of the wells 54. In the example configuration shown in FIG. 5, the support members 80 have a height, relative to the depth of the wells 54 and relative to the average stud length, so that the studs 40 do not touch the well bottoms 56. Thus, until the first conductive material 60 cures or cools to a solid form after immersing the studs 40 therein, the chip 22 may be entirely supported by the support members 80. After the first conductive material 60 becomes solidified and the underfill material 30 is placed between the chip 22 and the substrate 24, the first conductive material 60 and the underfill material 30 may also contribute to supporting and holding the chip 22 in place. Although underfill material 30 is shown in the first and second embodiments of FIGS. 2-5, in other embodiments (not shown) there may be no underfill material, as it may not be needed and/or desired. This may provide additional flexibility in the structure for relieving stress.

The height of, shape of, placement, and number of support members 80 may vary for an embodiment of the present invention, as will be apparent to one of ordinary skill in the art. Also, the depth and width (or diameter) of the wells 54 may vary for an embodiment of the present invention. The cross-section shape of the wells 54 may vary as well, including (but not limited to) being round, oval, square, rectangular, or with rounded corners, for example. And, the wire size, ball size, and stud length may vary for an embodiment of the present invention. As an illustrative example, the wells 54 may have a depth of about 200 μm and a diameter of about 100 μm, the studs 40 may have a wire diameter of about 50 μm and a length of about 300 μm, and the support members 80 may have a height of about 150 μm. Hence, in such case, the space between the first chip side 44 and the first substrate side 50 may be about 150 μm, the tips of the studs 40 will be about 50 μm from the well bottoms 56, and about 150 μm of the stud 40 will be immersed in the first conductive material 60 (assuming the first conductive material 60 fills the well 54 after inserting the stud 40 in this case), for example. In other embodiments, the studs 40 may have a length between about 50 μm and about 300 μm, and a wire diameter between about 30 μm and about 50 μm, for example.

The amount of the first conductive material 60 placed in each well 54 may vary so that the well 54 is filled, less than filled, or overflowing with the first conductive material 60 after inserting the studs 40. If the first conductive material 60 overfills a well 54 after the insertion of a stud 40 therein, the excess portions of the first conductive material 60 will likely cling to and wet the sides of the studs 40 above the substrate surface; thus avoiding the spreading of excess portions of the first conductive material 60 across the first substrate side 50, which may cause unwanted shorts. Thus, such wetting or wicking of the studs 40 with the first conductive material 60 may be a preferred and advantageous feature of the design. In a preferred embodiment, the first conductive material 60 just fills a well 54 (see e.g., FIGS. 3 and 5) or just slightly overfills a well 54 (wicking to the stud 40) to maximize the contact area between the stud 40 and the first conductive material 60. In other embodiments, however, the amount of first conductive material 60 may underfill the wells 54 after inserting the studs 40. As with the first embodiment, the first conductive material 60 may be solder, for example.

In a preferred embodiment, the substrate may be a low-cost substrate 24 having a thicker first substrate layer 48 with wells 54 formed therein (e.g., rather than bump landing pads), for example. Also, in other embodiments (not shown), the substrate 24 may be a configuration other than BGA, such as a substrate 24 with pins or leads extending from the second substrate side 70 or other sides of the substrate, for example. With the benefit of this disclosure, one of ordinary skill in the art will realize many other variations on substrate designs while incorporating the bottomed wells 54 for an embodiment of the present invention. Also, the placement and array configuration of the chip contact pads 42 (and thus the studs 40) on a chip 22 may vary widely, as will be apparent to one of ordinary skill in the art.

Another advantage of an embodiment of the present invention is that stress concentrations normally experienced at solder joints in a solder bump configuration (see e.g., FIG. 1) may be significantly reduced. Such stresses are often caused by coefficient of thermal expansion (CTE) mismatch between the chip 22, the solder bumps 26 (see e.g., FIG. 1), and the substrate 24. With a structural configuration provided by an embodiment of the present invention, such CTE mismatch may have less impact and may exert less stress on the bonding joints at the chip 22, and/or the structure of an embodiment may be able to handle much higher stresses (as compared to a solder bump configuration). Also, reducing stress on the chip caused by CTE mismatch and other sources of stress is important when the chip 22 incorporates weak dielectric materials (e.g., low-k and ultra-low-k dielectric materials) in the intermetal dielectric layers, as is becoming more common. The studs 40 may allow for more lateral flexibility than solder bumps, which will contribute to relieving thermal stresses caused by CTE mismatch, rather than just transmitting the stresses to the chip 22. Thus, it is preferred that the studs 40 be made from a flexible material (e.g., gold) rather than a rigid material.

Although studs 46 are shown and described in the first and second embodiments of FIGS. 2-5 as being formed from a wire that initially had a ball-shaped tip, in other embodiments (not shown) the initial shape of the wire tip may vary. For example, the initial wire tip may have not specially formed shape after the severing for forming the prior stud. The stud may be formed on the chip contact pad with a wedge bond, for example. Or, the initial shape of the wire tip may have formed into some other shape (i.e., other than a ball shape), for example. With the benefit of this disclosure, one of ordinary skill in the art may realize other possible variations for the studs 46.

Although embodiments of the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor chip package comprising:
an integrated circuit chip;
a chip contact pad formed on a first side of the chip;
a stud formed on the chip contact pad, the stud being formed from wire using a wire bonding machine, the stud having an elongated portion extending from the chip contact pad;
a substrate comprising
a first layer of insulating material on a first side of the substrate,
a well formed in the first layer and opening to the first side of the substrate, the well having a bottom,
a first conductive material that at least partially fills the well, and
a second layer having conductive trace lines formed therein, wherein the first conductive material is electrically connected to at least one of the trace lines; and
wherein the stud is partially embedded in the first conductive material to form an electrical connection between the chip and the substrate, and wherein the first side of the chip faces the first side of the substrate.

2. The semiconductor chip package of claim 1, further comprising:
a conductive liner at least partially lining the well, wherein the first conductive material in the well is electrically connected to the at least one trace line via the conductive liner.

3. The semiconductor chip package of claim 1, wherein the conductive liner comprises copper.

4. The semiconductor chip package of claim 1, wherein the stud comprises gold and wherein the outermost surface of the contact pad comprises gold.

5. The semiconductor chip package of claim 1, wherein the insulating material of the first substrate layer comprises an organic material.

6. The semiconductor chip package of claim 1, wherein the first conductive material comprises solder.

7. The semiconductor chip package of claim 1, wherein the first conductive material comprises a conductive adhesive.

8. The semiconductor chip package of claim 1, wherein the substrate further comprises:
two or more layers having conductive trace lines formed therein;
a second side opposite the first side,
a terminal on the second side,
a via filled with a second conductive material, wherein the terminal is electrically connected to the second conductive material in the via, wherein the second conductive material is electrically connected to at least one of the conductive trace lines, and wherein the terminal is electrically connected to the chip contact pad via the stud, the first conductive material, at least one of the conductive trace lines, and the second conductive material.

9. The semiconductor chip package of claim 1, further comprising:
a support member extending from the first layer of the substrate between the chip and the substrate, wherein the chip is at least partially supported by the support member.

10. The semiconductor chip package of claim 9, wherein the support member comprises polymer material.

11. The semiconductor chip package of claim 1, further comprising an underfill material located between the chip and the substrate.

12. The semiconductor chip package of claim 1, wherein the stud has a partially squashed ball portion bonded to the chip contact pad, and wherein the elongated portion extends from the partially squashed ball portion.

13. A method of forming a semiconductor chip package, comprising:
wire bonding a wire onto a chip contact pad on a first side of an integrated circuit chip with a wire bonding machine;
severing the wire so that an elongated portion of the wire remains extending from the chip contact pad to form a stud;
immersing at least part of the elongated portion of the stud into a first conductive material to form an electrical connection between the chip and a substrate, wherein the first conductive material is formed in a well, wherein the well is formed in a first layer of the substrate, wherein the well opens to a first side of the substrate, wherein the well has a bottom, wherein the first conductive material is electrically connected to a trace line formed in a second layer of the substrate, wherein the first substrate layer is over the second substrate layer, and such that the first side of the chip faces the first side of the substrate.

14. The method of claim 13, wherein the wire has a ball-shaped tip prior to the wire bonding, and wherein the ball-shaped tip becomes partially squashed against the chip contact pad during the wire bonding.

15. The method of claim 13, wherein the first conductive material comprises a conductive adhesive, and wherein the method further comprises:
at least partially filling the well with the first conductive material; and
curing the first conductive material after the immersing.

16. The method of claim 13, wherein the first conductive material comprises solder, and wherein the method further comprises at least partially melting the solder before the immersing.

17. A semiconductor chip package comprising:
an integrated circuit chip;
a chip contact pad formed on a first side of the chip;
a stud formed on the chip contact pad, the stud having an elongated portion extending from the ship contact pad;
a substrate comprising
a first layer of insulating material on a first side of the substrate,
a well formed in the first layer and opening to the first side of the substrate, the well having a bottom,
a conductive liner at least partially lining the well,
a first conductive material that at least partially fills the well, and
a second layer having conductive trace lines formed therein, wherein the first conductive material is electrically connected to at least one of the trace lines via the conductive liner; and
a support member extending from the first layer of the substrate between the chip and the substrate, wherein the stud is partially embedded in the first conductive material to form an electrical connection between the chip and the substrate, wherein the first side of the chip faces the first side of the substrate, and wherein the chip is at least partially supported by the support member.

18. The semiconductor chip package of claim 17, wherein the stud has a partially squashed ball portion bonded to the chip contact pad, and wherein the elongated portion extends from the partially squashed ball portion.

19. The semiconductor chip package of claim 17, wherein the first conductive material comprises solder.

20. The semiconductor chip package of claim 17, wherein the first conductive material comprises a conductive adhesive.
